(19) United States
(12) Patent Application Publication
(10) Pub. No.: US 2012/0026684 A1
(43) Pub. Date: Feb. 2, 2012

(54) Computer holding apparatus

(76) Inventor: Christopher Robert Matthews, Temecula, CA (US)

(21) Appl. No.: 13/136,124

(22) Filed: Jul. 25, 2011

Related U.S. Application Data
(60) Provisional application No. 61/368,577, filed on Jul. 28, 2010.

(51) Int. Cl. G06F 1/16; F16B 2/20; F16B 2/06; F16M 13/02; H05K 7/00

(52) U.S. Cl. 361/679.58; 248/226.11; 211/26

(57) ABSTRACT

The instant invention pertains to a holding apparatus for a computer device. The holding apparatus includes a case member; an adjustable clamping member; an elongated adjustable neck member between the case member and the clamping member; a removable cup holding coin tray; and a cleat member for securing the apparatus to surfaces including a wall, furniture, or a shelf, and allows a user to operate the computer device without having to actively hold and support it.

### PRIORITY

Priority is claimed to Provisional Application No. 61/368,577 filed on Jul. 28, 2010.

### FIELD OF INVENTION

This invention generally relates to a computer holding apparatus. Moreover, it pertains specifically to an apparatus for holding a touch screen tablet computer, notebook computer, e-book reader, or flat screen personal digital assistant (“PDA”) that allows the user to both protect the computer or PDA and operate the computer or PDA without needing to actively hold the computer, e-book reader, or PDA.

### BACKGROUND OF THE INVENTION

Recently, tablets, e-book reader, PDA's and notebook computers have become very functional and popular. A person, with the aid of a PDA, such as an iPhone®, notebook or tablet computer, such as an iPad®, e-book reader, such as a Kindle®, can now perform most of functions that used to be only possible with a powerful desktop or laptop computer. The increased functionality and popularity of the PDA and tablet computer has allowed users to further untether themselves from the typical office environment, and work from whatever location in which they happen to be. Unfortunately, the lack of a stable work space in many locations prevents the user from comfortably working on a PDA or notebook computer. For example, if a user decides that he or she is going to work in a fully reclined position on a bed or couch, there is no simple way for the user to work and, simultaneously hold aloft the PDA or tablet computer. Although some solutions for this have been made available, these solutions are typically not very functional, not well built, not well designed, not robust enough, do not securely hold the computer, and/or do not allow a user to use the solution in a wide variety of spaces. Thus, what is needed is a computer holding apparatus that securely holds the computer, allows the user to attach the apparatus to a wide variety of surfaces, and allows the user to easily shift the position of the computer.

A deficiency of the prior art configurations pertains to the ability to mount to irregular surfaces, unstable surfaces, or surfaces that cannot offer a support portion for a clamping member to clamp on to. The instant invention includes a cleat member that is adapted to be removably and securely attached to any desired surface that is then used for attaching the clamping member thereto. This advancement is very important since on many occasions a user is traveling and needs to affix their device to many different types of surfaces during their travels, and in many cases they cannot due to the shape or stability of the surfaces available, or the lack of a suitable mounting surface at all.

Another deficiency of the prior art configurations pertains to the ability of the existing case members to conform to the shape of whichever device is desired to be held in place. The case member of the instant invention includes a plurality of holding arms that also includes an adjustable holding arm. The adjustable arm includes an adjustment mechanism and a locking element, such that it can be adjusted in a direction radiating inwardly and outwardly from a center point of the case member, such that when a computer device is placed between the holding arms, the adjustable holding arm is used to tighten the grip of the case member upon the device and locks it in place. Therefore, devices of differing shapes and sizes can be held removably and securely by the current invention.

A further deficiency of the prior art configurations pertains to the ability to hold securely devices of heavier weights than a normal hand held device. The apparatus of the instant invention includes a stronger neck design than the prior art by incorporating a steel flexible gooseneck cable that can hold up to 5 pounds. The adjustable neck member may also incorporate a gap filling rubberized cover and a stiffening support rod to increase its strength even further. The end of the neck is adjustably attached to the case member and securely holds a device in place and allows it to be rotated 360 degrees on two axes. This dexterity, along with the flexible, bendable gooseneck cable allows the invention to be positioned in virtually any angle for maximum viewing comfort and also offers hands free operation. No other portable computing device holder can be detached from its base and used as an independent tabletop stand in either landscape or portrait mode or can be used as a protective transport case. This provides safety and security to the device when traveling with the computing device and prevents damage from bumps, scratches and low grade drops.

### SUMMARY OF THE INVENTION

To minimize the limitations in the prior art, and to minimize other limitations that will become apparent upon reading and understanding the present specification, the present invention discloses a computer holding apparatus that has a flexible, yet stiff, articulating cable, a vice attachment, and a locking clip.

One embodiment of this invention is an apparatus, for holding a computer, comprising a case; a cable; and an attachment device. The case is configured to hold a computer and the attachment device is configured to attach to a plurality of different surfaces. Preferably the cable allows a user to position said computer in a variety of positions. Additionally, the case is further comprised of a locking element and an adjustable arm. The adjustable arm is held in place by engaging the locking element to prevent the case from allowing the computer to slip out of the case. Preferably the computer is selected from the group consisting of a notebook computer, a personal digital assistant or tablet, and an e-book reader.

The preferred embodiment of the invention includes a cleat member. The cleat member is attached or anchored to a surface and the attachment device is then attached to said cleat. This allows the device to be used with surfaces that the attachment device cannot engage with directly.

An object of the present invention is to provide a functional, safe, and easy to use computer device holder that will overcome the deficiencies of the prior art.

Other features and advantages are inherent in the computer holding case claimed and disclosed will become apparent to those skilled in the art from the following detailed description and its accompanying drawings.

### BRIEF DESCRIPTION OF THE DRAWINGS

FIG. 1 is an illustration of a front view of one embodiment of the computer holding apparatus.

FIG. 2 is an illustration of a side view of the one embodiment of the computer holding apparatus of FIG. 1.

FIG. 3 is an illustration of a side view of one embodiment of the computer holding apparatus of FIG. 1.

FIG. 4 is an illustration of a perspective view of the cleat member.

FIG. 5 is an illustration of a perspective view of the case member of the apparatus holding a computer device.

FIG. 6A is an illustration showing a cup holding coin tray adapted to be attached between the cleat member and a surface.

FIG. 6B is an illustration showing the cup holding coin tray attached to the cleat member.

FIG. 7 is an illustration showing the combination of the computer holding apparatus and a computer device.

FIG. 8 is an illustration of a second embodiment of the adjustable neck member and a gap filling rubberized cover and a stiffening support rod.

FIG. 9A is an illustration showing a side view of an embodiment of the computer holding apparatus.

FIG. 9B is an illustration showing a perspective view of the embodiment of the computer holding apparatus of FIG. 9A along with the cleat member and cup holding coin tray connected therewith.

FIG. 9C is an illustration showing a bottom view of the embodiment of the case member of FIG. 9A.

### DESCRIPTION OF THE PREFERRED EMBODIMENT

In the following detailed description of the preferred embodiment, reference is made to the accompanying drawings that form a part hereof, and in which is shown by way of illustration a specific embodiment in which the invention may be practiced. It is to be understood that other embodiments may be utilized and structural changes may be made without departing from the scope of the present invention.

In the following detailed description of various embodiments of the invention, numerous specific details are set forth in order to provide a thorough understanding of various aspects of one or more embodiments of the invention. However, one or more embodiments of the invention may be practiced without these specific details. In other instances, well-known methods, procedures, and/or components have not been described in detail so as not to unnecessarily obscure aspects of embodiments of the invention.

The invention is a new holding apparatus for a computer, preferably the iPad®, that is arbitrarily mounted and used in multiple locations whether or not there is a horizontal mounting surface such as a table that exists at the desired location. The holding apparatus preferably includes a mounting cleat that is installed or mounted to a wall or other surface for interacting with the computer at any angle or position.

Although the holding apparatus is designed primarily for indoors, and for holding an iPad®, the unit can be used anywhere there is a suitable mounting surface. The cleat or wall mounting unit allows for secure mounting to almost any vertical or horizontal surface. Each holding apparatus preferably includes at least one wall mounting element and at least two mounting screws. The holding apparatus has a clamp that engages with the wall mounting element. The back of the case can be made in the shape of a cartoon character, which would be pleasing to children.

### REFERENCE NUMERAL LIST

10—Computer holding apparatus
11—iPad®/iPhone®/e-book reader/computing device
12—Case member
13—Retaining clips
14—Adjustable upper retaining arm
15—Upper edge restraining arms
16—Lower bracket arms
17—Adjustment knob
18—Locking element
19—Adjustment gear
20—Rack portion of upper retaining clip arm
21—Lock/Release lever for flex gooseneck cable
22—Lock/Release casing and Flex Cable Holder element
23—Cable retention/threaded connector
24—Flex Gooseneck Cable element
30—Clamping device/integral Cable attachment
31—Wall Mount element/used with Clamp 30
25—Cleat Backing Member
26—Cleat Holding Member
32—Back member for the cup holding tray
33—Back connector portion of case member 12
34—Connector portion (between the back member and coin tray portion) of the cup holding coin tray
35—Tray portion of the cup holding tray
36—Cup holder portion of the cup holding tray
37—Removable fasteners for the backing member of the cleat member
38—Gap filling rubberized cover for the adjustable neck member
39—Stiffening support rod for the adjustable neck member
40—Case backing member
41—Adjustable arm member for case backing member 40
42—Adjustable connector member between case backing member 40 and adjustable arm member 41
43—Releasable locking member for adjustable connector member 42

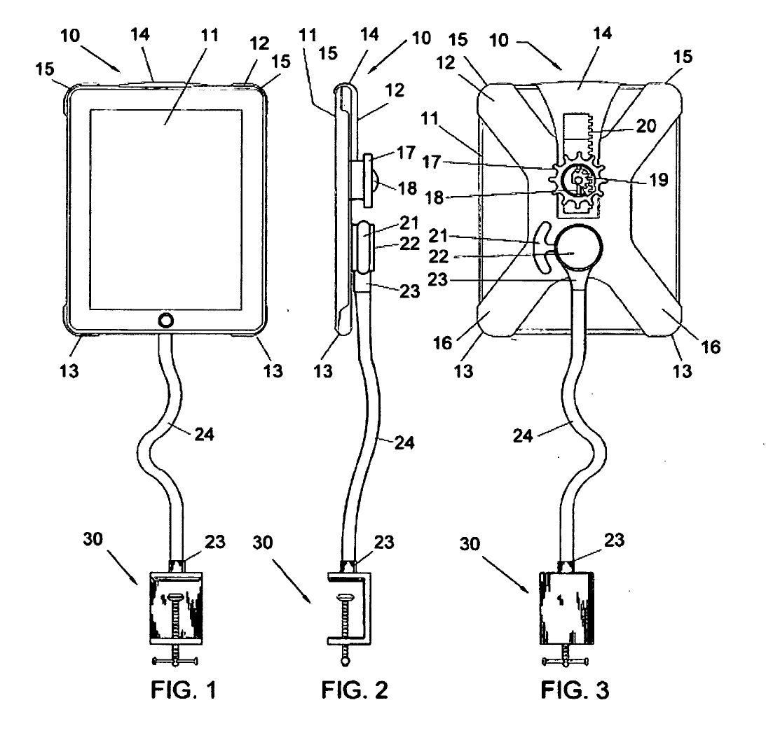

FIG. 1 is an illustration of a front view of one embodiment of the computer holding apparatus 10. FIG. 1 shows that a notebook or tablet computer 11 is being securely held by a case 12. The case 12 preferably includes arms 14, 15, and 16, and resilient clips 13 at the ends of the lower arms 16. FIG. 1 also includes a cable or articulating arm 24. This arm 24 is preferably flexible, yet stiff, such that the computer is posable or positionable. The end of the neck is adjustably attached to the case member 12 and securely holds a device in place and allows it to be rotated 360 degrees on two axes. This dexterity, along with the flexible, bendable gooseneck cable allows the invention to be positioned in virtually any angle for maximum viewing comfort and also offers hands free operation. This provides safety and security to the device when traveling with the computing device and prevents damage from bumps, scratches and low grade drops. Once the user positions the computer and case, the cable firmly holds its shape and the position of the computer and case. FIG. 1 also shows how the apparatus preferably includes an attachment device or clamp that allows the apparatus to be attached to shelves, headboards, desktops, and many other types of surfaces. FIG. 1 also shows that the attachment device may be a standard C-clamp with a screw vice mechanism.

FIG. 2 is an illustration of a side view of one embodiment of the computer holding apparatus. FIG. 2 shows how clips 13 and arm 14 curve around the sides of the computer to firmly and securely hold the computer in place. FIG. 2 also shows how the cable is connected to the back of the main part of the case 12. FIG. 2 also shows the side of the adjustment knob 17 and locking element 18.

FIG. 3 is an illustration of a rear view of one embodiment of the computer holding apparatus. FIG. 3 shows how the cable 24 is attached to the case at threaded connector 23 with respect to the case 12 and computer 11. By using the lock release lever 21 to lock and unlock the casing release 22 with respect to case 12. FIG. 3 also shows how adjustable arm 14 is tightened and loosened by using a ratcheting adjustment knob 17 with rack 20. Locking element 18 is engaged to make sure that the clip arm 14 doesn't accidentally loosen and allow the computer to slip out of the case 12. Turning the adjustment knob 17, the gear driven adjustable arm 14 locks the computer securely in place. When the arm is lowered, it securely holds the computer in place and prevents it from dislodging due an accidental collision or bump.

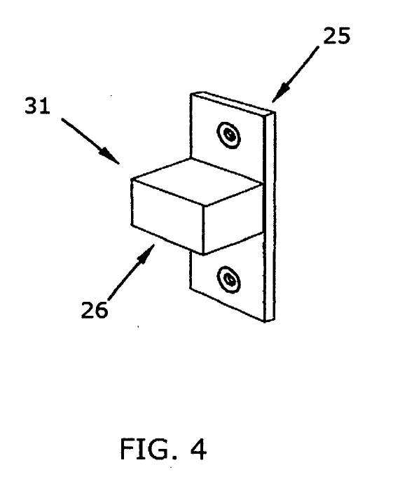

FIG. 4 is an illustration of a perspective view of the cleat of one embodiment of the computer holding apparatus. The wall mount element or cleat 31 is preferably attached to a wall or other surface by removably attaching the cleat backing member 25 using removable fasteners 37, which allows the apparatus 10 to be used with non-lipped, flat, or even unstable surfaces. Cleat holding member 26 is the used as the clamping portion for clamp member 30 to removably and securely clamp thereto.

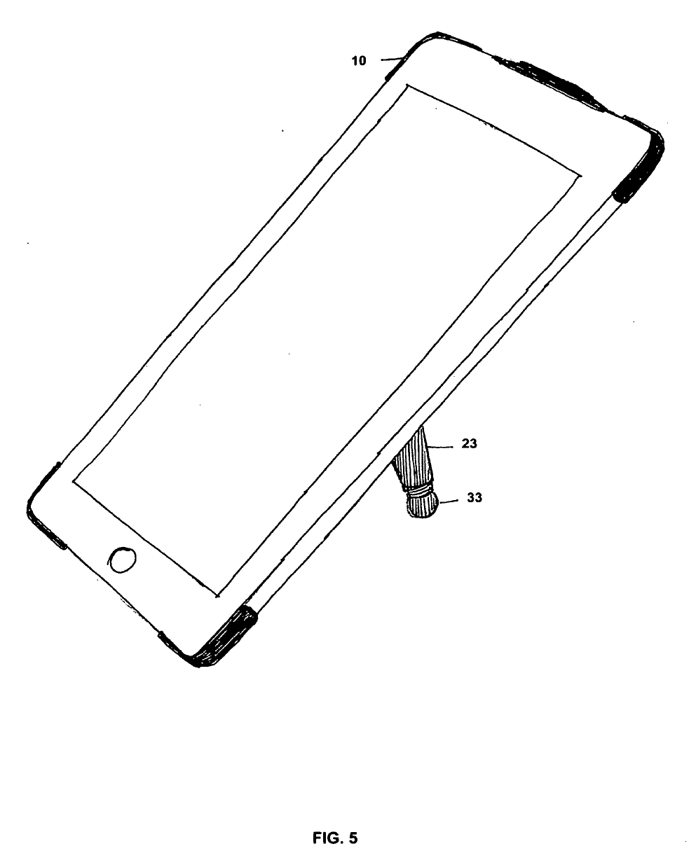

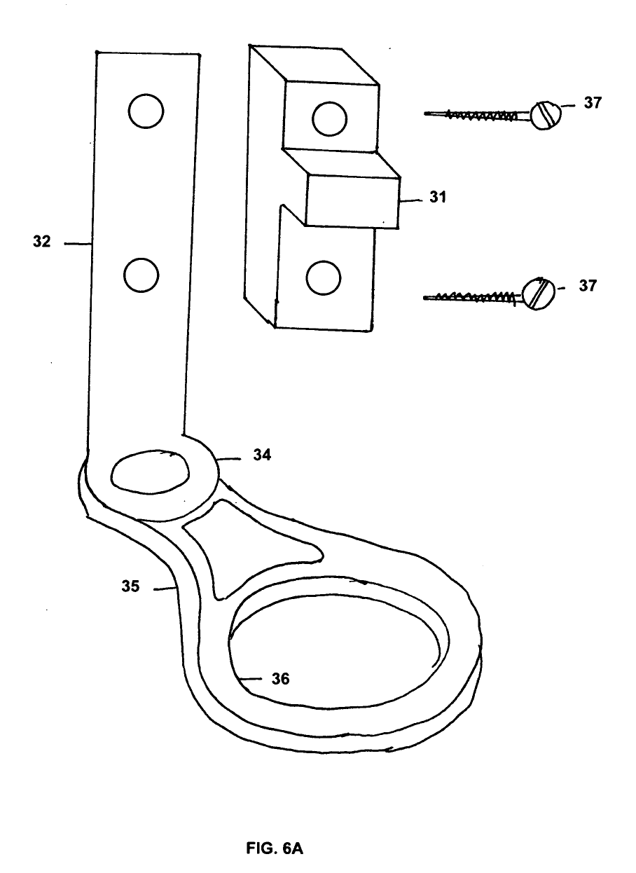

FIG. 5 is an illustration of a perspective view of the case member holding a computer device.

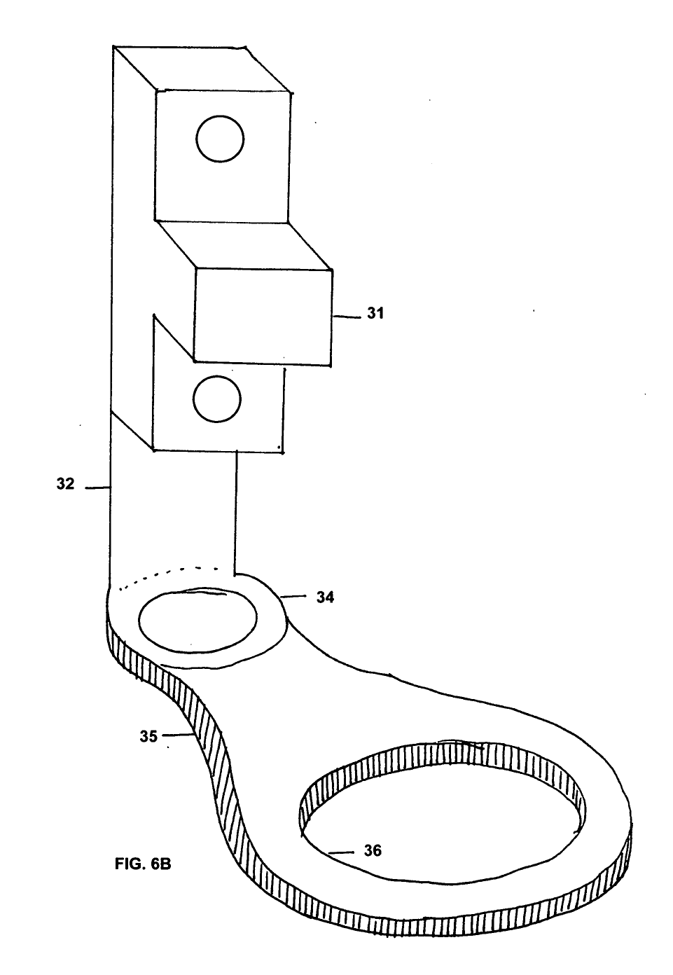

As shown in FIGS. 6A and 6B, the apparatus may further include a cup holding coin tray that includes a back member 32, a tray portion 35, and a cup holding portion 36, and is adapted to be attached between the cleat member and a surface. This feature allows a user to place a beverage within the cup holder and near their computer device for easy access.

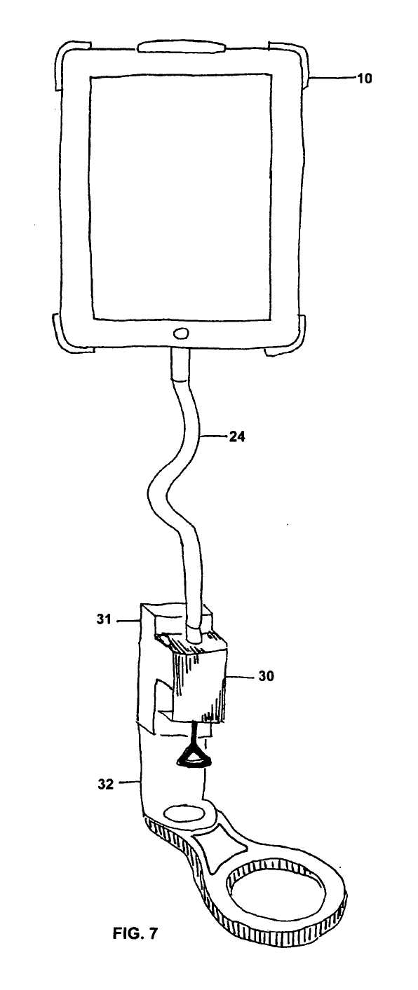

FIG. 7 is an illustration of a perspective view of the combination of a computer device and the preferred embodiment of the computer holding apparatus.

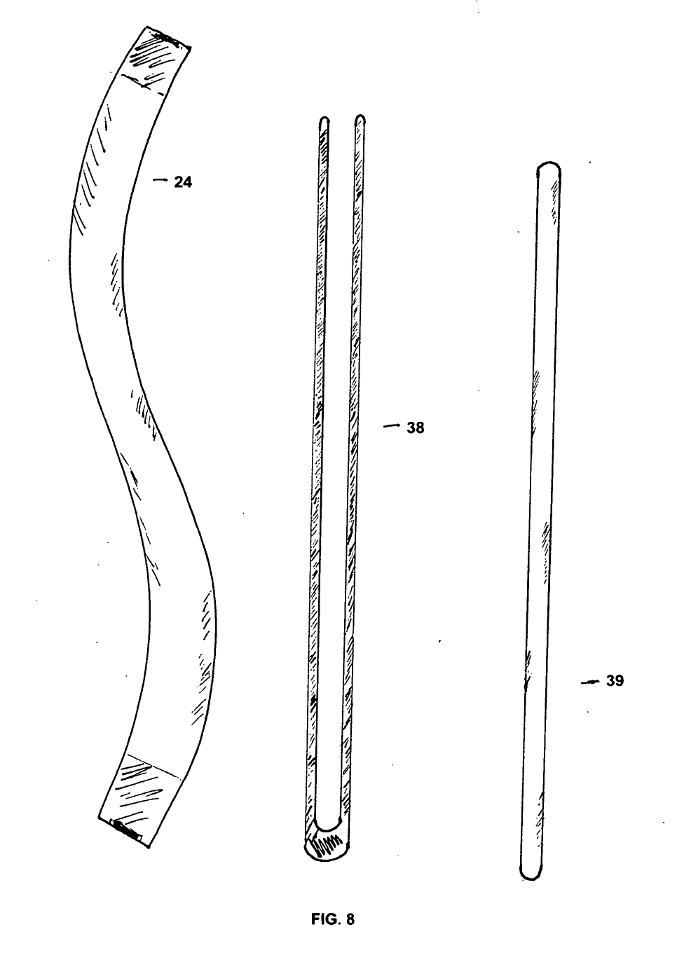

FIG. 8 shows a gap filling rubberized cover 38 and a stiffening support rod 39 that are adapted to be used in conjunction with the adjustable neck member 24 and are designed to allow the apparatus to hold heavier devices without the neck member bending out of position or collapsing.

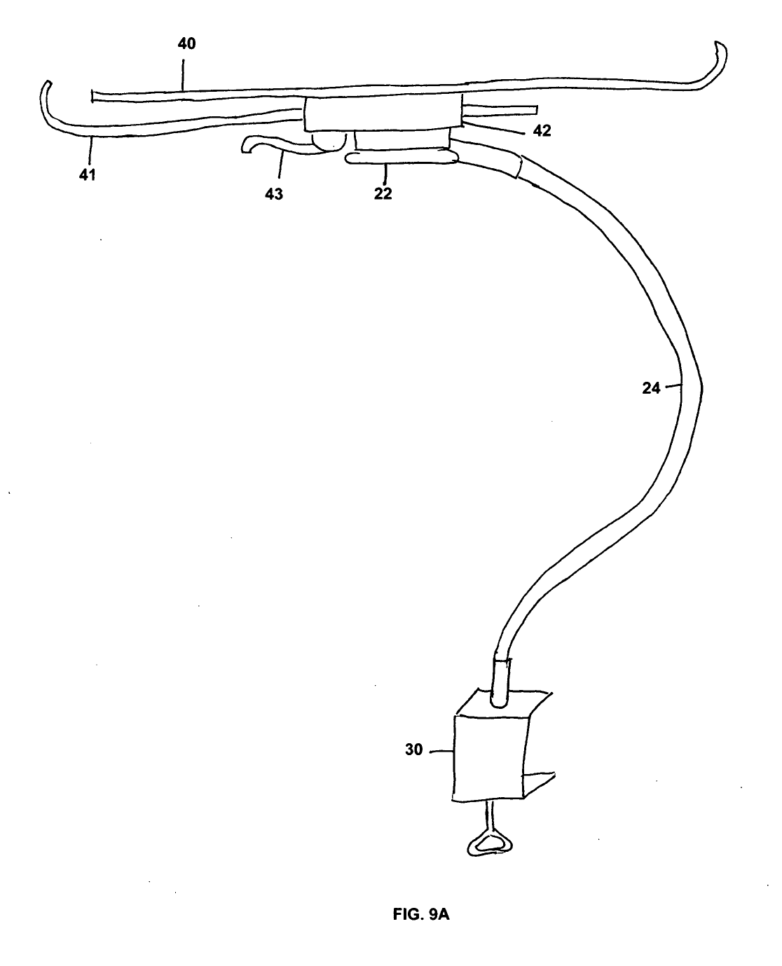

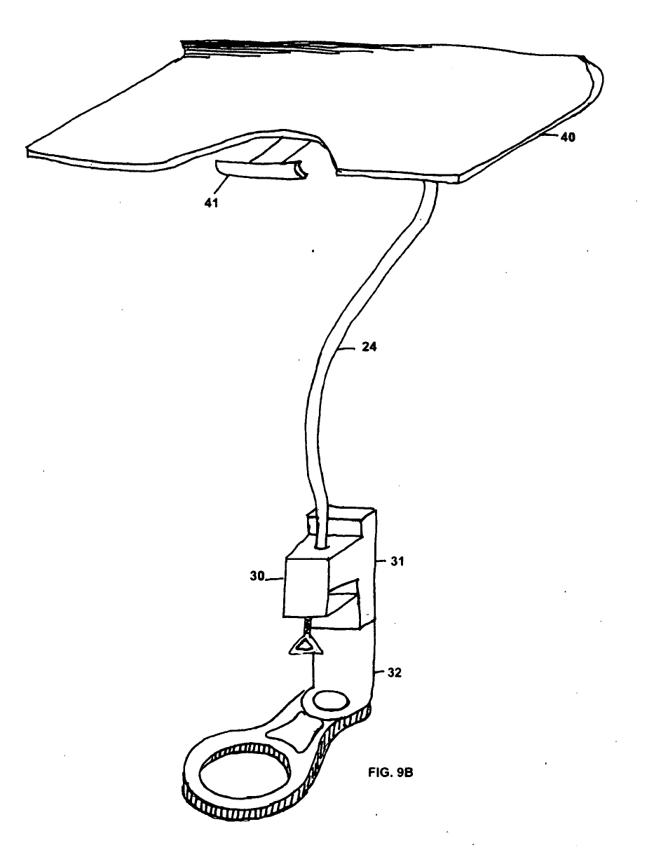

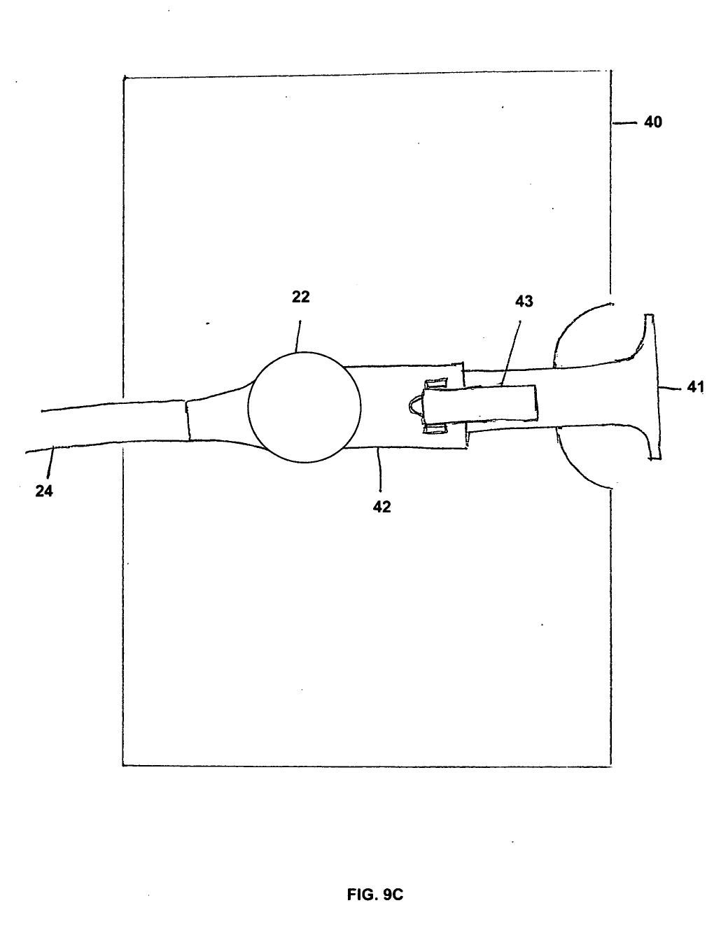

FIGS. 9A-9C show the case member being formed using two arms 40 and 41, with adjustable connector member 42 therebetween, and incorporating releasable locking member 43 therebetween to ensure a tight hold on the chosen computer device.

The foregoing description of the preferred embodiment of the invention has been presented for the purposes of illustration and description. While multiple embodiments are disclosed, still other embodiments of the present invention will become apparent to those skilled in the art from the above detailed description, which shows and describes illustrative embodiments of the invention. As will be realized, the invention is capable of modifications in various obvious aspects, all without departing from the spirit and scope of the present invention. Accordingly, the detailed description is to be regarded as illustrative in nature and not restrictive. Also, although not explicitly recited, one or more embodiments of the invention may be practiced in combination or conjunction with one another. Furthermore, the reference or non-reference to a particular embodiment of the invention shall not be interpreted to limit the scope the invention. It is intended that the scope of the invention not be limited by this detailed description, but by the claims and the equivalents to the claims that are appended hereto.

What is claimed is:

1. A computer holding apparatus comprising a case member; an adjustable clamping member; an elongated adjustable neck member removably connected to and between said case member and said clamping member; and a cleat member adapted to be fixedly secured to any surface, such that said clamping member can be quickly and easily removably secured to said cleat member, wherein said holding apparatus is adapted to adjustably hold a computer device so that a user can operate said device without actively holding said device.

2. The computer holding apparatus of claim 1, wherein said case member includes a plurality of clips interconnected at a center point and are adapted to removably and securely hold said computer device thereupon; and wherein one of said plurality of clips is adjustable.

3. The computer holding apparatus of claim 2, wherein said adjustable clip includes a ratchet mechanism, a ratchet adjustment knob, and a locking element, such that said clip can be adjusted in a direction radiating inwardly and outwardly from said center point, such that when said computer device is placed between said plurality of said clips, said adjustable clip and ratchet mechanism is used to tighten the grip of said case member upon said device and lock it in place.

4. The computer holding apparatus of claim 3, wherein said ratchet mechanism is a linear ratchet mechanism including rack and pinion members.

5. The computer holding apparatus of claim 2, wherein said plurality of clips include four static clips and one adjustable clip, such that said four static clips are flexible and form a shape resembling the letter ‘X’, and wherein said adjustable clip includes a mechanism, an adjustment knob, and a locking element, such that said clip can be adjusted in a direction radiating inwardly and outwardly from said center point, such that when said computer device is placed between said plurality of said clips, said adjustable clip is used to tighten the grip of said case member upon said device and lock it in place.

6. The computer holding apparatus of claim 1, wherein said adjustable clamping member is formed as an adjustable C-clamp adapted to removably and securely clamp to said cleat member.

7. The computer holding apparatus of claim 1, wherein said cleat member is formed having a backing member, and a holding member protruding therefrom and is adapted to removably and securely receive said clamping member thereon; and wherein said backing member includes at least one removable fastener adapted to removably and securely attach said cleat to said stable surface.

8. The computer holding apparatus of claim 1, further comprising a cup holding coin tray adapted to be connected between said cleat member and said surface; said cup holder tray including a backing member, and a cup holder member extending perpendicularly to said backing member.

9. The computer holding apparatus of claim 1, wherein said elongated adjustable neck member is articulating and removably connected to said case member using interdigitating threads and a releasable locking member; and wherein said elongated adjustable neck member is removably connected to said clamping member using interdigitating threads.

10. The computer holding apparatus of claim 9, wherein said elongated adjustable neck member is a steel flexible gooseneck cable.

11. The computer holding apparatus of claim 10, wherein said elongated adjustable neck member includes a gap filling rubberized cover and a stiffening support rod.

12. A combination of a computer device and a holding apparatus, wherein said computer device is chosen from a group of computer devices including smart phones, tablets, personal digital assistants (PDA's), miniature laptops, and laptops; and said holding apparatus comprises a case member adapted to securely and removably hold said computer device; an adjustable clamping member; an elongated adjustable neck member removably connected to and between said case member and said clamping member; and a cleat member adapted to be fixedly secured to any surface, such that said clamping member can be quickly and easily removably secured to said cleat member, wherein said holding apparatus is adapted to adjustably hold said computer device so that a user can operate said device without actively holding said device.

13. The combination of claim 12, wherein said case member includes a plurality of clips interconnected at a center point and are adapted to removably and securely hold said computer device thereupon; and wherein one of said plurality of clips is adjustable.

14. The combination of claim 13, wherein said adjustable clip includes a ratchet mechanism, a ratchet adjustment knob, and a locking element, such that said clip can be adjusted in a direction radiating inwardly and outwardly from said center point, such that when said computer device is placed between said plurality of said clips, said adjustable clip and ratchet mechanism is used to tighten the grip of said case member upon said device and lock it in place.

15. The combination of claim 14, wherein said ratchet mechanism is a linear ratchet mechanism including rack and pinion members.

16. The combination of claim 13, wherein said plurality of clips include four static clips and one adjustable clip, such that said four static clips are flexible and form a shape resembling the letter ‘X’, and wherein said adjustable clip includes a mechanism, an adjustment knob, and a locking element, such that said clip can be adjusted in a direction radiating inwardly and outwardly from said center point, such that when said computer device is placed between said plurality of said clips, said adjustable clip is used to tighten the grip of said case member upon said device and lock it in place.

17. The combination of claim 12, wherein said adjustable clamping member is formed as an adjustable C-clamp adapted to removably and securely clamp to said cleat member.

18. The combination of claim 12, wherein said cleat member is formed having a backing member, and a holding member protruding therefrom and is adapted to removably and securely receive said clamping member thereon; and wherein said backing member includes at least one removable fastener adapted to removably and securely attach said cleat to said stable surface.

19. The combination of claim 12, wherein said elongated adjustable neck member is a steel flexible gooseneck cable that is articulating and removably connected to said case member using interdigitating threads and a releasable locking member; and wherein said elongated adjustable neck member is removably connected to said clamping member using interdigitating threads; and wherein said elongated adjustable neck member includes a gap filling rubberized cover and a stiffening support rod.

20. The computer holding apparatus of claim 12, further comprising a cup holding coin tray adapted to be connected between said cleat member and said surface; said cup holder tray including a backing member, and a cup holder member extending perpendicularly to said backing member.
